(19) United States
(12) Patent Application Publication
(10) Pub. No.: US 2006/0278956 A1
(43) Pub. Date: Dec. 14, 2006

(54) Semiconductor wafer with non-rectangular shaped dice

(75) Inventor: Eitan Cadouri, Cupertino, CA (US)

Correspondence Address: MORRISON & FOERSTER LLP, 425 MARKET STREET, SAN FRANCISCO, CA, 94105-2482, US

(73) Assignee: PDF SOLUTIONS, INC., SAN JOSE, CA (US)

(21) Appl. No.: 10/548,699

(22) PCT Filed: Mar. 12, 2004
(86) PCT No.: PCT/US04/07827

§ 371 Date: Sep. 8, 2005

Related U.S. Application Data
(60) Provisional application No. 60/453,921, filed on Mar. 13, 2003.

(51) Int. Cl. H01L 23/544

(52) U.S. Cl. 257/620

(57) ABSTRACT

A semiconductor wafer having a plurality of dice formed on the wafer. The plurality of dice having non-rectangular shapes with at least one notched corner. A plurality of saw streets are defined between the plurality of dice. At an intersection of two of the plurality of saw streets, a distance is defined between corners of two adjacent dice that is greater than a minimum distance between the two adjacent dice.

### CROSS-REFERENCE TO RELATED APPLICATION

This application claims the benefit of U.S. Provisional Application No. 60/453,921, titled A PROCESS OF BETTER DESIGNING RETICLE FIELDS, filed Mar. 13, 2003, the entire content of which is incorporated herein by reference.

### BACKGROUND

1. Field of the Invention

The present application relates generally to integrated circuit design and fabrication on a semiconductor wafer and, more particularly, to fabricating non-rectangular dice among a plurality of saw streets on a semiconductor wafer.

2. Related Art

In semiconductor wafer processing, integrated circuits (ICs) are formed on a semiconductor wafer. In general, layers of various materials, which are either semiconducting, conducting or insulating, are utilized to form the ICs. These materials are doped, deposited and etched using various well-known processes to form the ICs. Each semiconductor wafer is processed to form a large number of individual regions containing ICs known as dice. Test circuits, test pads and alignment markings may also be formed on the wafer in regions between the dice referred to as saw streets.

Following the integrated circuit formation process and before dice are separated, a full wafer may be tested. While multiple dice are attached together on a single wafer, semiconductor manufactures often perform wafer level testing of the dice. The test circuits and test pads formed in the saw streets between the dice are used to assist in performing the wafer level testing of the dice. Wafer level testing identifies bad dice before further effort is expended in testing and packaging. Therefore, wafer level testing allows a manufacturer to identify and discard unsatisfactory dice.

Following testing, the wafer is diced to separate the individual dice from one another for packaging or for use in an unpackaged form within larger circuits. Two techniques for wafer dicing include scribing and sawing. With scribing, a diamond tipped scribe is moved across the wafer surface along pre-formed scribe lines. These scribe lines extend along the saw street between the dice. Any test circuits, test pads and alignment marks positioned in a saw street are sacrificed. Thus, these structures can be referred to as sacrificial structures.

As mask layout tolerances decrease and cutting techniques improve, there may also be a corresponding decrease in distance between individual dice on a semiconductor wafer. Therefore, the width of the saw streets between individual dice may also narrow. The resulting saw streets may leave little room for sacrificial structures.

### SUMMARY

In one exemplary embodiment, a semiconductor wafer has a plurality of dice formed on the wafer. The plurality of dice having non-rectangular shapes with at least one notched corner. A plurality of saw streets are defined between the plurality of dice. At an intersection of two of the plurality of saw streets, a distance is defined between corners of two adjacent dice that is greater than a minimum distance between the two adjacent dice.

### DESCRIPTION OF DRAWING FIGURES

The present application can be best understood by reference to the following description taken in conjunction with the accompanying drawing figures, in which like parts may be referred to by like numerals:

FIG. 1 shows a side view of an exemplary reticle positioned over a semiconductor wafer.

FIG. 2 shows a plan view of the reticle depicted in FIG. 1.

FIG. 3 shows a plan view of structures formed on a wafer using the reticle depicted in FIGS. 1 and 2.

FIGS. 4-7 show additional plan views of structures formed on a wafer.

### DETAILED DESCRIPTION

The following description sets forth numerous specific configurations, parameters, and the like. It should be recognized, however, that such description is not intended as a limitation on the scope of the present invention, but is instead provided as a description of exemplary embodiments.

Circuit designers provide circuit pattern data, which describes a particular IC design, to a reticle production system, or reticle writer. The circuit pattern data is typically in the form of a representational layout of the physical layers of the fabricated IC device. The representational layout typically includes a representational layer for each physical layer of the IC device (e.g., gate oxide, polysilicon, metallization, etc.). The representational layout may also include one or more representational layers defining structures positioned over sacrificial areas (e.g., over saw streets). These sacrificial structures may include alignment markings, identification markings, measurement markings, test pads, test circuitry, and the like.

The reticle writer uses the circuit pattern data to write (e.g., using an electron beam writer or laser scanner to expose a reticle pattern) a plurality of reticles that will later be used to fabricate the particular IC design and sacrificial structures.

A reticle or photomask is an optical element containing at least transparent and opaque regions, and sometimes semi-transparent and phase shifting regions, as well, which together define the pattern of coplanar features in an electronic device such as an IC and sacrificial structures. Reticles are used during a photolithographic process to define specified regions of a semiconductor wafer for etching, ion implantation, or other fabrication process. For many modern IC designs, an optical reticle's features are between about one and about five times larger than the corresponding features on the wafer. For other exposure systems (e.g., x-ray, e-beam, and extreme ultraviolet) a similar range of reduction ratios also apply.

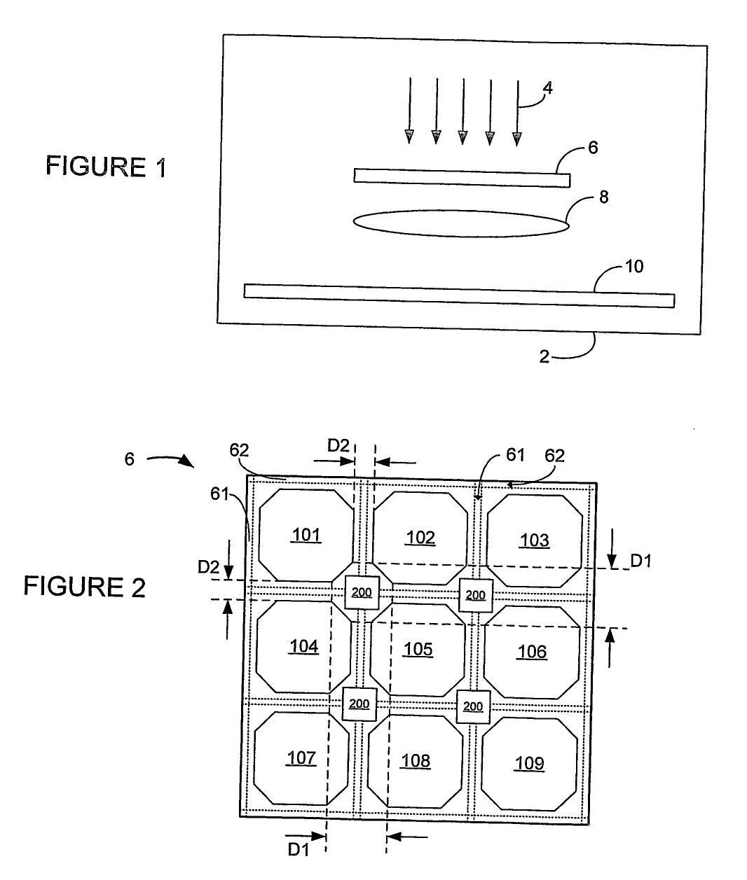

FIG. 1 depicts an exemplary embodiment of a reticle 6 positioned over a wafer 10 during IC fabrication in a chamber 2. The chamber 2 exposes the reticle 6 with laser light 4 or the like. Light that passes through the reticle 6 is directed with a lens 8 to the wafer 10. A photolithographic process may use one or more reticles to simultaneously create a plurality of integrated circuits and sacrificial structures on the wafer. Thus, a wafer may contain several to thousands of separate integrated circuits.

A single wafer may be divided along boundaries between the individual devices by scoring or cutting along axes referred to as scribe lines in the saw streets. Some or all of the sacrificial structures may be destroyed during dicing. Separation or dicing may be performed by sawing, laser cutting, and the like.

FIG. 2 depicts reticle 6 defining a plurality of die images 101-109, which can be used to form dice on a wafer through a photolithographic process. In the present exemplary embodiment, die images 101-109 have non-rectangular shapes with at least one notched corner. A plurality of saw street regions 61, 62 are defined between die images 101-109. At an intersection of two saw street regions 61, 62, a distance D1 is defined between the corners of two adjacent die images that is greater than a minimum distance D2 between the two adjacent die images.

In the present exemplary embodiment, die images 101-109 also have at least one side not parallel to saw street regions 61, 62. Note that because die images 101-109 have non-rectangular shapes, saw street regions 61, 62 are non-rectilinear. In FIG. 2, saw street regions 61, 62 are depicted as being orthogonal to at least one side of die images 101-109. It should be recognized, however, that saw street regions 61, 62 can be non-orthogonal to any sides of die images 101-109. In FIG. 2, die images 101-109 are depicted as having an octagonal shape. It should be recognized, however, that die images 101-109 can have various shapes, such as hexagonal shapes. Additionally, for simplicity and convenience, the figure shows structures and features having similar horizontal or vertical dimensions in a plane parallel to a wafer. It should be recognized, however, that the horizontal and vertical dimensions can differ.

As depicted in FIG. 2, reticle 6 also includes sacrificial structure images 200, which can be used to form sacrificial structures on a wafer through a photolithographic process. In the present exemplary embodiment, sacrificial structure images 200 are disposed at the intersection of two saw street regions 61, 62, where distance D1 defined between the corners of two adjacent die images is greater than minimum distance D2 between two adjacent die images. Thus, sacrificial structure images 200 can have a dimension, such as a width, greater than minimum distance D2, and the width of saw street regions 61, 62 is not limited to and can be less than the at least one dimension of sacrificial structure images 200. In FIG. 2, sacrificial structure images 200 are depicted as having at least one side orthogonal to saw street regions 61, 62. It should be recognized, however, that sacrificial structure images 200 can have at least one side non-orthogonal to saw street regions 61, 62.

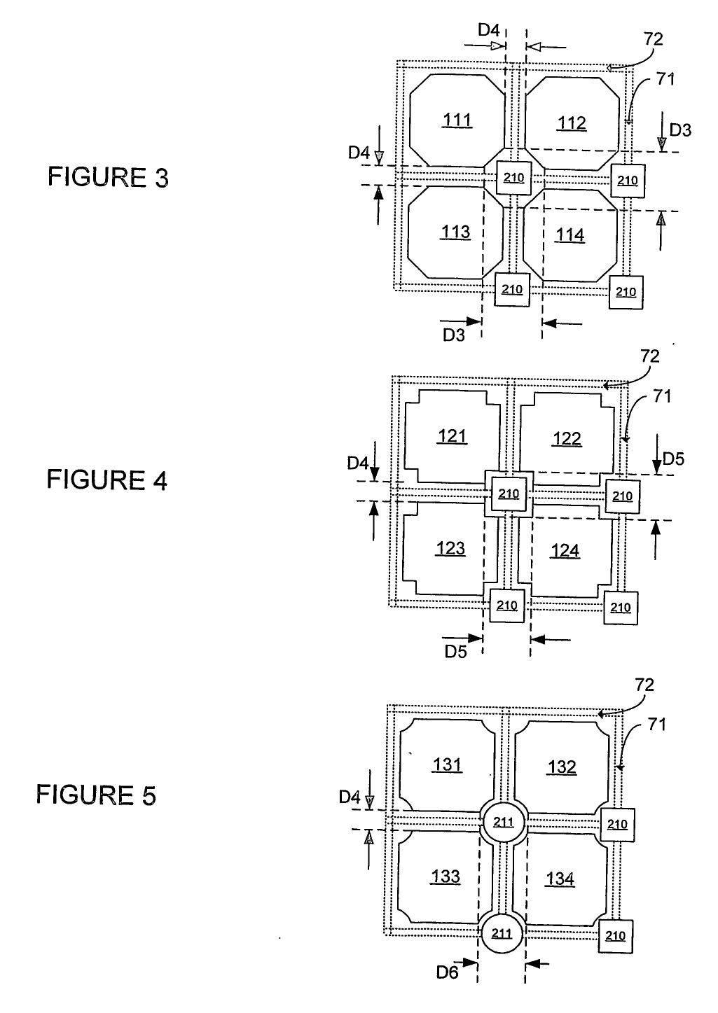

FIG. 3 depicts structures formed on a wafer using reticle 6 (FIG. 2). For example, dice 111-114 are formed on the wafer from die images 101, 102, 104, and 105 (FIG. 2) on reticle 6 (FIG. 2). In the present exemplary embodiment, because dice 111-114 are formed using reticle 6 (FIG. 2), they are formed with non-rectangular shapes with at least one notched corner. A plurality of saw streets 71, 72 are defined between dice 111-114. At an intersection of two saw streets 71, 72, a distance D3 is defined between the corners of two adjacent dice that is greater than a minimum distance D4 between the two adjacent dice.

In the present exemplary embodiment, dice 111-114 also have at least one side not parallel to saw streets 71, 72. Note that because dice 111-114 have non-rectangular shapes, saw streets 71, 72 are non-rectilinear. In FIG. 3, saw streets 71, 72 are depicted as being orthogonal to at least one side of dice 111-114. It should be recognized, however, that saw streets 71, 72 can be non-orthogonal to any sides of dice 111-114.

Additionally, sacrificial structures 210 are formed on the wafer from sacrificial structure images 200 (FIG. 2) on reticle 6 (FIG. 2). In the present exemplary embodiment, because sacrificial structures 210 are formed using reticle 6 (FIG. 2), they are disposed at the intersection of two saw streets 71, 72, where distance D3 defined between the corners of two adjacent dice is greater than minimum distance D4 between two adjacent dice. Thus, sacrificial structures 210 can have at least one dimension, such as a width, greater than minimum distance D4, and the width of saw streets 71, 72 is not limited to and can be less than the at least one dimension of sacrificial structures 210. In FIG. 3, sacrificial structures 210 are depicted as having at least one side orthogonal to saw streets 71, 72. It should be recognized, however, that sacrificial structures 210 can have at least one side non-orthogonal to saw streets 71, 72.

Although dice 111-114 are depicted as having an octagonal shape, it should be recognized that dice 111-114 can have various non-rectangular shapes, such as hexagonal shapes. For example, FIG. 4 depicts an exemplary embodiment of dice 121-124 with square-notched corners. As depicted in FIG. 4, at an intersection of saw streets 71, 72, a distance D5 defined between the square-notched corners of two adjacent dice is greater than minimum distance D4.

FIG. 5 depicts another exemplary embodiment of dice 131-134 with curve-notched corners. As depicted in FIG. 5, at an intersection of saw streets 71, 72, a distance D6 defined between the curve-notched corners of two adjacent dice is greater than minimum distance D4.

FIG. 5 also depicts sacrificial structures 210 having a square shape and sacrificial structures 211 having a circular shape. It should be recognized that sacrificial structures 210, 211 can have various shapes.

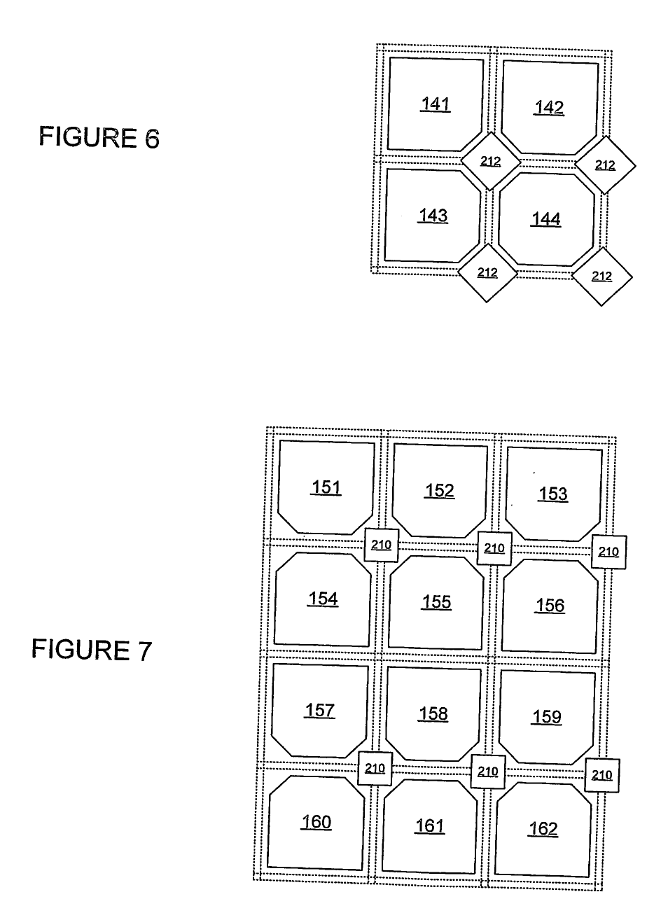

FIG. 6 depicts still another exemplary embodiment of dice 141-144 with non-rectangular shapes that are not identical to each other in shape. FIG. 6 also depicts sacrificial structures 212 having a diamond shape.

FIG. 7 depicts yet another exemplary embodiment of dice 151-162 with non-rectangular shapes and an edge that can be used to orient dice 151-162. For example, after dicing the wafer, the shape of a die can be used to orient the die before packaging the die. Additionally, in the present exemplary embodiment, alternating rows of dice have similar orientations. After dicing, the alternating rows of dice can be oriented based on any remaining sacrificial structures 210.

Although exemplary embodiments have been described, various modifications can be made without departing from the spirit and/or scope of the present invention. Therefore, the present invention should not be construed as being limited to the specific forms shown in the drawings and described above.

I claim:

1. A semiconductor wafer comprising:
a plurality of dice formed on the wafer, the plurality of dice having non-rectangular shapes with at least one notched corner; and
a plurality of saw streets defined between the plurality of dice,
wherein at an intersection of two of the plurality of saw streets, a distance is defined between corners of two adjacent dice that is greater than a minimum distance between the two adjacent dice.

2. The semiconductor wafer of claim 1, wherein the plurality of dice have at least one side not parallel and non-orthogonal to the saw streets.

3. The semiconductor wafer of claim 1, wherein the plurality of dice have octagonal shapes.

4. The semiconductor wafer of claim 1, wherein the plurality of dice have hexagonal shapes.

5. The semiconductor wafer of claim 1, wherein the at least one notched corner is square or curved.

6. The semiconductor wafer of claim 1, wherein the saw streets are non-rectilinear.

7. The semiconductor wafer of claim 1, wherein the saw streets are orthogonal to at least one side of the plurality of dice.

8. The semiconductor wafer of claim 1, wherein the saw streets are non-orthogonal to any sides of the plurality of dice.

9. The semiconductor wafer of claim 1, further comprising:
a sacrificial structure formed at the intersection of two of the plurality of saw streets.

10. The semiconductor wafer of claim 9, wherein the sacrificial structure has at least one dimension greater than the minimum distance between the two adjacent dice.

11. The semiconductor wafer of claim 10, wherein a width of the plurality of saw streets is less than the at least one dimension of the sacrificial structure.

12. The semiconductor wafer of claim 9, wherein at least one side of the sacrificial structure is orthogonal to the plurality of saw streets.

13. The semiconductor wafer of claim 9, wherein at least one side of the sacrificial structure is non-orthogonal to the plurality of saw streets.

14. A reticle to form the plurality of dice and plurality of saw streets in accordance with claim 1 using a photolithographic process.

15. A semiconductor wafer comprising:
a plurality of dice formed on the wafer, the plurality of dice having non-rectangular shapes;
a plurality of saw streets defined between the plurality of dice; and
a sacrificial structure formed at an intersection of two of the plurality of saw streets, wherein at the intersection a distance is defined between two adjacent dice that is greater than a minimum distance between the two adjacent dice.

16. The semiconductor wafer of claim 15, wherein the plurality of dice have at least one side not parallel to the saw streets.

17. The semiconductor wafer of claim 15, wherein the plurality of dice have octagonal or hexagonal shapes.

18. The semiconductor wafer of claim 15, wherein the plurality of dice have at least one notched corner, square-notched corner or curve-notched corner.

19. The semiconductor wafer of claim 15, wherein the saw streets are non-rectilinear.

20. The semiconductor wafer of claim 15, wherein the sacrificial structure has at least one dimension greater than the minimum distance between the two adjacent dice.

21. The semiconductor wafer of claim 20, wherein a width of the plurality of saw streets is less than the at least one dimension of the sacrificial structure.

22. A reticle for use in forming structures on a semiconductor wafer, the reticle comprising:
a plurality of die images having non-rectangular shapes with at least one notched corner; and
a plurality of saw street images defined between the plurality of die images,
wherein at an intersection of two of the plurality of saw street images, a distance is defined between corners of two adjacent die images that is greater than a minimum distance between the two adjacent die images.

23. The reticle of claim 22 further comprising:
a sacrificial structure image disposed at the intersection of two of the plurality of saw street images, wherein the sacrificial structure image has at least one dimension greater than the minimum distance between the two adjacent die images.

24. A method of forming structures on a semiconductor wafer, the method comprising:
forming a plurality of dice having non-rectangular shapes with at least one notched corner; and
forming a plurality of saw streets defined between the plurality of dice,
wherein at an intersection of two of the plurality of saw streets, a distance is defined between corners of two adjacent dice that is greater than a minimum distance between the two adjacent dice.

25. The method of claim 24 further comprising:
forming a sacrificial structure at the intersection of two of the plurality of saw streets, wherein the sacrificial structure has at least one dimension greater than the minimum distance between the two adjacent dice.
